(19) United States
(12) Patent Application Publication
(10) Pub. No.: US 2026/0156939 A1
(43) Pub. Date: Jun. 4, 2026

(54) ARRAY SUBSTRATES, DISPLAY PANELS AND METHODS OF MANUFACTURING ARRAY SUBSTRATES

(71) Applicant: Guangzhou China Star Optoelectronics Semiconductor Display Technology Co., Ltd., Guangzhou, Guangdong (CN)

(72) Inventors: Yanhong MENG, Guangzhou (CN); Wei LIU, Guangzhou (CN)

(21) Appl. No.: 18/253,926

(22) PCT Filed: Mar. 30, 2023
(86) PCT No.: PCT/CN2023/084914

§ 371 Date: May 23, 2023

(30) Foreign Application Priority Data
Feb. 23, 2023 (CN) 202310168276.X

(51) Int. Cl. H10D 86/40; H10D 86/01

(52) U.S. Cl. CPC H10D 86/451; H10D 86/0221

(57) ABSTRACT

An array substrate sequentially includes a substrate, an active layer, a first metal layer, and a second passivation layer. The array substrate further includes a hydrogen barrier layer disposed between the active layer and the second passivation layer and covering at least a channel region, and a moisture discharge hole disposed to penetrate through at least the flat layer.

### TECHNICAL FIELD

The present disclosure relates to a field of display technology, and more particularly, to array substrates, display panels, and methods of manufacturing the array substrates.

### BACKGROUNDS

Referring to FIG. 1, in the LCD display panel, since water molecules in a flat layer 70 and hydrogen ions in a second passivation layer 90 are prone to penetrate into a channel region 3 of an active layer 40, when the channel region 3 of the active layer 40 is invaded by more hydrogen ions and more water molecules, it is prone to cause an ESD diode structure to have a negative offset of voltage, resulting in abnormal display, causing a phenomenon such as a black screen.

Therefore, a conventional array substrate has a technical problem that the negative offset of voltage occurs in the ESD diode structure.

### SUMMARY

Embodiments of the present disclosure provide array substrates, display panels, and methods of manufacturing the array substrates, which may alleviate a technical problem of a negative offset of voltage in an ESD diode structure existing in a conventional array substrate.

An embodiment of the present disclosure provides an array substrate including:
a substrate;
an active layer disposed above the substrate;
a first metal layer disposed at a side of the active layer away from the substrate, the first metal layer including a source and a drain, the active layer including doped regions in contact with the source and the drain, and a channel region between adjacent doped regions;
a first passivation layer disposed at a side of the first metal layer away from the substrate;
a flat layer disposed at a side of the first passivation layer away from the substrate;
a second passivation layer disposed at a side of the flat layer away from the substrate;
the array substrate further includes at least one hydrogen barrier layer disposed between the active layer and the second passivation layer, the hydrogen barrier layer covers at least the channel region, and the array substrate is further provided with a moisture discharge hole disposed through at least the flat layer.

Alternatively, in some embodiments of the present disclosure, the moisture discharge hole is disposed to penetrate through at least the flat layer.

Alternatively, in some embodiments of the present disclosure, a depth of the moisture discharge hole is equal to a thickness of the flat layer.

Alternatively, in some embodiments of the present disclosure, the hydrogen barrier layer above any of the channel regions is disposed continuously.

Alternatively, in some embodiments of the present disclosure, the moisture discharge hole is disposed through the flat layer and the hydrogen barrier layer, and at least a portion of the second passivation layer is disposed within the moisture discharge hole.

Alternatively, in some embodiments of the present disclosure, a distance between an edge of the moisture discharge hole and an edge of the channel region is greater than 10 microns.

Alternatively, in some embodiments of the present disclosure, the array substrate further includes a common electrode layer disposed between the flat layer and the second passivation layer, the hydrogen barrier layer is disposed in the same layer as the common electrode layer.

Alternatively, in some embodiments of the present disclosure, the common electrode layer includes a common electrode, and the hydrogen barrier layer and the common electrode are spaced apart from each other.

Alternatively, in some embodiments of the present disclosure, the hydrogen barrier layer is formed of the same material as the common electrode layer.

Alternatively, in some embodiments of the present disclosure, the moisture discharge hole is disposed to penetrate through the flat layer, and the hydrogen barrier layer is filled within the moisture discharge hole.

Optionally, in some embodiments of the present disclosure, the moisture discharge hole is disposed to penetrate through the flat layer, the hydrogen barrier layer, and the second passivation layer, the array substrate further includes a pixel electrode layer disposed at a side of the second passivation layer away from the substrate, the pixel electrode layer is filled in the moisture discharge hole.

Alternatively, in some embodiments of the present disclosure, the hydrogen barrier layer is disposed at a side of the first passivation layer away from the substrate, and the flat layer is disposed at a side of the hydrogen barrier layer away from the substrate.

Alternatively, in some embodiments of the present disclosure, a depth of the moisture discharge hole is less than a thickness of the flat layer.

Alternatively, in some embodiments of the present disclosure, a part of the moisture discharge holes are disposed to penetrate through the flat layer, and each of another part of the moisture discharge holes has a depth that is less than the thickness of the flat layer.

Alternatively, in some embodiments of the present disclosure, the moisture discharge holes are arranged at equal intervals.

Alternatively, in some embodiments of the present disclosure, the material of forming the hydrogen barrier layer includes at least one of indium tin oxide, indium zinc oxide, or indium gallium zinc oxide.

Alternatively, in some embodiments of the present disclosure, the array substrate further includes a second metal layer disposed on the substrate, the second metal layer includes a gate, the source is connected to the gate.

An embodiment of the present disclosure provides a display panel including an array substrate as described in any of the above embodiments.

An embodiment of the present disclosure provides a method of manufacturing an array substrate comprising:
providing a substrate;
forming a second metal layer, a gate insulating layer, an active layer, a first metal layer, and a first passivation layer on the substrate in sequence;
depositing a layer of PFA organic material over the first passivation layer, and treating the PFA organic material by a photo process to form a flat layer including a moisture discharge hole;
depositing a layer of transparent semiconductor material over the flat layer, and treating the transparent semiconductor material by the photo process to form a hydrogen barrier layer and a common electrode layer provided in a same layer; and
depositing an inorganic material over the common electrode layer and the hydrogen barrier layer to form a second passivation layer.

Alternatively, in some embodiments of the present disclosure, the forming of the hydrogen barrier layers and the forming of the second passivation layer further comprises: depositing an entire layer of a material of the hydrogen barrier layers, then depositing an entire layer of an inorganic material, and performing the photo process on the material of the hydrogen barrier layer and the inorganic material using one photomask to form the hydrogen barrier layer and the second passivation layer. The moisture discharge hole penetrates through the flat layer, the hydrogen barrier layers, and the second passivation layer.

### Beneficial Effect

A hydrogen barrier layer is disposed above a channel region of an ESD diode structure, the hydrogen barrier layer is disposed at a side of the active layer away from the substrate, the hydrogen barrier layer is disposed at a side of the second passivation layer facing the substrate, the hydrogen barrier layer is disposed to cover at least the channel region, so that hydrogen ions in the second passivation layer are blocked from diffusing into the channel region of the active layer by the hydrogen barrier layer, water molecules in the flat layer are discharged through a moisture discharge hole through at least the flat layer, the invasion and influence of water molecules and hydrogen ions to the channel region are reduced, thereby alleviating a technical problem that a negative offset of voltage of an ESD diode structure in an existing array substrate.

### BRIEF DESCRIPTION OF THE DRAWINGS

In order to more clearly explain the technical solutions in the embodiments of the present disclosure, the following will briefly describe the drawings required in the description of the embodiments. It is apparent that the drawings in the following description are only some embodiments of the present disclosure. For those skilled in the art, without paying any creative work, other drawings may be obtained based on these drawings.

FIG. 1 is a schematic cross-sectional view of an array substrate according to the related art.

FIG. 2 is a first cross-sectional view of an array substrate according to the present disclosure;

FIG. 3 is a second cross-sectional view of an array substrate according to the present disclosure;

FIG. 4 is a third cross-sectional view of an array substrate according to the present disclosure;

FIG. 5 is a schematic flow chart of a method of manufacturing the array substrate according to the present disclosure;

FIGS. 6A and 6B are flow charts of a first state of an array substrate according to the present disclosure;

FIGS. 7A and 7B are flow charts of a second state of an array substrate according to the present disclosure;

FIGS. 8A to 8E are flow charts of a third state of an array substrate according to the present disclosure.

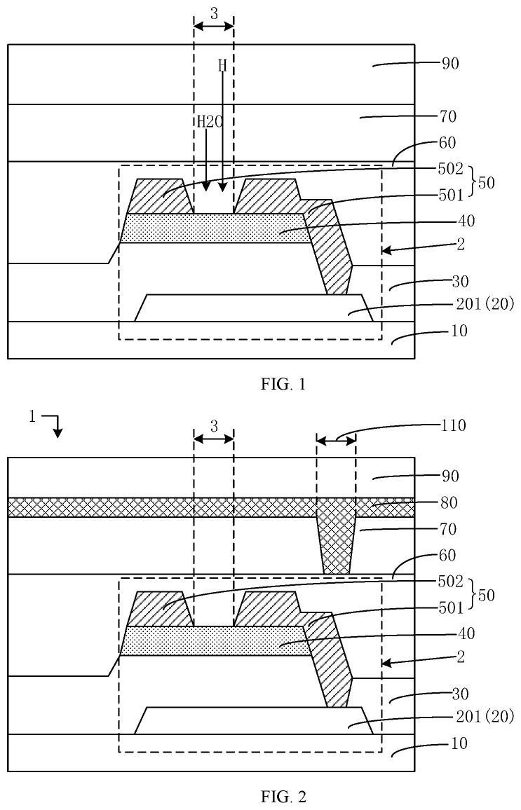

### LIST OF REFERENCE SIGNS

| Reference | | Reference | |
|---|---|---|---|
| signs | Part name | signs | Part name |
| 10 | Substrate | 20 | Second metal layer |
| 30 | Gate insulating layer | 40 | Active layer |
| 50 | First metal layer | 60 | First passivation layer |
| 70 | Flat layer | 80 | Hydrogen barrier layer |
| 90 | Second passivation layer | 100 | Pixel electrode layer |
| 201 | Gate | 501 | Source |
| 502 | Drain | 1 | Array substrate |
| 2 | ESD diode structure | 3 | Channel region |
| 110 | Moisture discharge hole | | |

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure. In addition, it should be understood that the specific implementations described here are only used to illustrate and explain the present disclosure, and are not used to limit the present disclosure. In the present disclosure, unless otherwise stated, directional words used such as “upper” and “lower” generally refer to the upper and lower directions of the device in actual use or working state, and specifically refer to the drawing directions in the drawings; and “inner” and “outer” refer to the outline of the device.

Referring to FIGS. 2, 3, and 4, an array substrate 1 provided in the present disclosure includes a substrate 10, an active layer 40, a first metal layer 50, a first passivation layer 60, a flat layer 70, and a second passivation layer 90, the active layer 40 is disposed above the substrate 10, the first metal layer 50 is disposed at a side of the active layer 40 away from the substrate 10, the first metal layer 50 includes a source 501 and a drain 502, the first passivation layer 60 is disposed at a side of the first metal layer 50 away from the substrate 10, the flat layer is disposed at a side of the first passivation layer 60 away from the substrate, and the second passivation layer 90 is disposed at a side of the flat layer 70 away from the substrate 10. The active layer 40 includes doped regions in contact with the source electrode 501 and the drain electrode 502, and a channel region 3 between adjacent doped regions, the array substrate 1 further includes at least one hydrogen barrier layer 80 disposed at a side of the active layer 40 away from the substrate 10, the hydrogen barrier layer 80 is disposed at a side of the second passivation layer 90 facing the substrate 10, and the hydrogen barrier layer 80 is disposed to cover at least the channel region 3.

The array substrate 1 further includes a second metal layer 20 and a gate insulating layer 30, the second metal layer 20 is disposed on the substrate 10, the second metal layer 20 includes a gate 201, the gate insulating layer 30 is disposed at a side of the second metal layer 20 away from the substrate 10, and the active layer 40 is disposed at a side of the gate insulating layer 30 away from the substrate 10.

The source 501 or the drain 502 is electrically connected to the gate 201, and the active layer, the gate, the source, and the drain constitute an ESD (Electro Static Discharge) diode structure.

The array substrate includes a display area and a non-display area, and the ESD diode structure 2 may be disposed in the non-display area.

In the present embodiment, the hydrogen barrier layer 80 is provided above the channel region 3 of the ESD diode structure 2, the hydrogen barrier layer 80 is provided at the side of the active layer 40 away from the substrate 10, the hydrogen barrier layer 80 is provided at the side of the second passivation layer 90 facing the substrate 10, and the hydrogen barrier layer 80 is provided to cover at least the channel region 3, so that hydrogen ions in the second passivation layer 90 are blocked from diffusing into the channel region 3 of the active layer 40 by the hydrogen barrier layer 80, and at the same time, water molecules in the flat layer are discharged by the moisture discharge hole 110 provided in the flat layer, thereby reducing invasion and influence of water molecules and hydrogen ions on the channel region, and alleviating the technical problem of the negative offset of voltage of the ESD diode structure 2 in the existing array substrate 1.

The technical solution of the present disclosure will now be described in connection with specific embodiments.

In the present disclosure, only the hydrogen barrier layer 80 above the ESD diode structure 2 is provided as an example to describe, and other solutions in which the hydrogen barrier layer 80 is provided above the active layer 40 so as to block the invasion of hydrogen ions and water molecules are equally applicable to the inventive concept of the present disclosure, and should also be included in the protective scope of the present disclosure. For example, for the bottom-gate TFT device, the hydrogen barrier layer 80 may also be provided over the channel region 3 of the active layer 40, so as to prevent the channel region 3 from being invaded by the upper hydrogen ions and water molecules which causes the abnormal display.

In an embodiment, referring to FIG. 2, the array substrate 1 is provided with a moisture discharge hole 110 at least through the flat layer 70.

Wherein a depth of the moisture discharge hole 110 is equal to a thickness of the flat layer 70.

It may be appreciated that the flat layer 7 is generally formed of an organic material, and because of the large amount of water molecules in the organic material, the water molecules easily invade the channel region 3 of the active layer 40, resulting in the negative offset of voltage of the ESD diode structure 2. By providing the moisture discharge hole 110 in the flat layer 70, the water molecules of the flat layer 70 may be discharged from the moisture discharge hole 110, thereby reducing the influence of the water molecules on the channel region 3 below, effectively preventing the negative offset of voltage of the ESD diode structure 2.

It should be noted that when the flat layer 70 is formed, the flat layer 70 is heated or baked to facilitate discharging of the water molecules along the moisture discharge hole 110, thereby reducing the content of the water molecules in the flat layer 70. Alternatively, after the flat layer 70 is formed, the display panel may be heated or baked when other film layers located on the flat layer 70 are formed. At this time, water molecules in the flat layer 70 may be discharged along the moisture discharge hole 110, thereby reducing the content of water molecules in the flat layer 70.

In the present embodiment, the water molecules in the flat layer 70 may be discharged along the moisture discharge hole 110 by providing the moisture discharge hole 110 through the flat layer 70, thereby reducing the content of the water molecules in the flat layer 70, improving the negative offset of voltage of the ESD diode structure 2, and improving the stability of the ESD diode structure 2.

In an embodiment, the number of the moisture discharge holes 110 may be plural, the plurality of the moisture discharge holes 110 may be arranged at intervals, and adjacent moisture discharge holes 110 may be equally spaced or unequally spaced. The layout of the moisture discharge holes 110 may be adjusted according to actual conditions, for example, the distribution density of the moisture discharge holes 110 may be increased at a position where there are more water molecules; alternatively, by providing the moisture discharge holes 110 at equal intervals, more moisture discharge holes 110 are provided, thereby improving the discharge efficiency of the water molecules in the flat layer 70.

It may be appreciated that when the moisture discharge hole 110 extends through the flat layer 70 only, the hydrogen barrier layer 80 is arranged to extend within the moisture discharge hole 110, and the hydrogen barrier layer 80 may prevent hydrogen ions in the second passivation layer 90 from entering the channel region 3 through the moisture discharge hole 110, so that the moisture discharge hole 110 need not be disposed away from the channel region 3.

It should be noted that the hydrogen barrier layer 80 is arranged continuously over any one of the ESD diode structures 2. The hydrogen barrier layer 80 is arranged continuously over any one of the ESD diode structures 2, thereby improving the blocking effect of the hydrogen barrier layer 80 on hydrogen ions in the second passivation layer 90.

It should be noted that when the moisture discharge hole 110 is arranged only through the flat layer 70, the hydrogen barrier layer 80 above any one of the ESD diode structures 2 is continuously arranged. In this case, the channel region 3 of the active layer 40 is not invaded by hydrogen ions, and is invaded by only a small amount of water molecules, that is, when the moisture discharge hole 110 is arranged only through the flat layer 70, no hydrogen ions invade the channel region 3, and a small amount of water molecules invade.

In an embodiment, the moisture discharge hole 110 may also be a groove having a depth that is less than the thickness of the flat layer 70.

In the present embodiment, by providing the groove which do not penetrate the flat layer 70 as the moisture discharge holes 110, the water molecules in the flat layer 70 are discharged by the groove, thereby enhancing the stability of the ESD diode structure. Further, since the flat layer isolates the second passivation layer from the first passivation layer, the possibility of hydrogen ion invasion may be reduced.

In yet another embodiment, a part of the moisture discharge holes 110 may be provided to penetrate through the flat layer, i.e., the depth of the moisture discharge hole 110 is provided to be equal to the thickness of the flat layer, while a part of the moisture discharge holes 110 are provided as grooves, i.e., the depth of the moisture discharge hole 110 is provided to be less than the thickness of the flat layer.

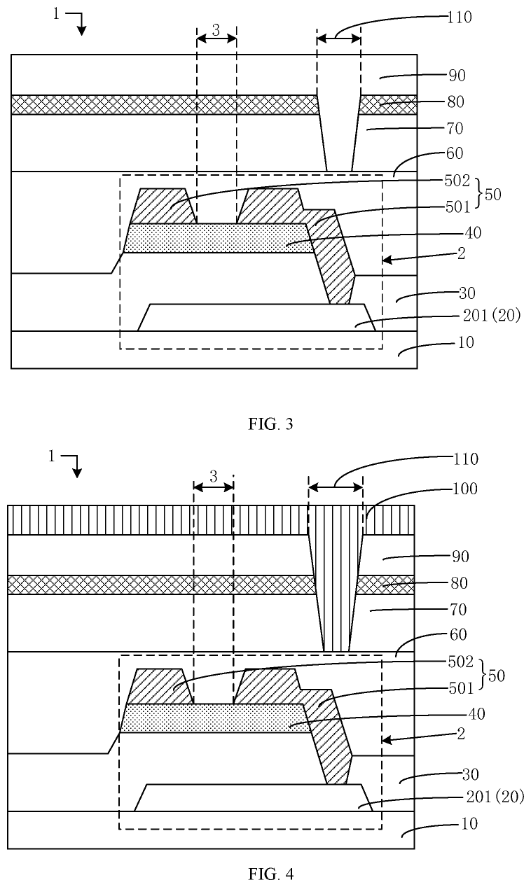

Referring to FIG. 3, a structure of an array substrate in this embodiment is substantially the same as that of the array substrate shown in FIG. 2, except that the moisture discharge hole 110 is further provided to penetrate through the hydrogen barrier layer 80.

It may be appreciated that the moisture discharge hole 110 is provided to penetrate through the flat layer 70 and the hydrogen barrier layer 80. When the flat layer 70 is formed, the flat layer 70 is heated or baked. At this time, a part of the water molecules in the flat layer 70 may be discharged. When the hydrogen barrier layer 80 is formed, the hydrogen barrier layer 80 is heated or baked. Since the hydrogen barrier layer 80 is also provided with the moisture discharge hole 110, a part of the water molecules in the flat layer 70 may be further discharged, so that the content of the water molecules in the flat layer 70 is further reduced, thereby reducing the water molecules that invade the channel region 3 of the active layer 40.

It should be noted that since the hydrogen barrier layer 80 serves to block the invasion of hydrogen ions in the second passivation layer 90 into the channel region 3, and the hydrogen barrier layer 80 is not provided in the moisture discharge hole 110, there may be invasion of hydrogen ions. Therefore, the moisture discharge hole 110 needs to be provided away from the channel region 3, thereby increasing the path length of the invasion of hydrogen ions into the channel region 3 and reducing the invasion of hydrogen ions into the channel region 3.

It should be noted that when the moisture discharge hole 110 is provided to penetrate through the flat layer 70 and the hydrogen barrier layer 80, the hydrogen barrier layer 80 is provided with the moisture discharge hole 110. When the second passivation layer 90 is formed, the channel region 3 may be invaded by a small amount of hydrogen ions. However, when the flat layer 70 is heated or baked, the water molecules of the flat layer 70 are partially discharged, and when the hydrogen barrier layer 80 is heated or baked, the water molecules of the flat layer 70 are further discharged. At the same time, the second passivation layer 90 is filled in the moisture discharge hole 110, so that the water molecules at a side of the second passivation layer 90 away from the substrate 10 may be blocked from entering the channel region 3 along the moisture discharge hole 110, that is, when the moisture discharge hole 110 is provided to penetrate through the flat layer 70 and the hydrogen barrier layer 80, the channel region 3 is invaded by a small amount of hydrogen ions, and is invaded by a tiny small amount of water molecules.

In the present embodiment, the moisture discharge holes 110 through the flat layer 70 and the hydrogen barrier layer 80 are provided so that a part of water molecules in the flat layer 70 are discharged when the flat layer 70 and the hydrogen barrier layer 80 are formed, thereby further reducing the water molecule content in the flat layer 70, and improving the stability of the ESD diode structure 2.

In an embodiment, referring to FIG. 3, a distance between an edge of the moisture discharge hole 110 and an edge of the channel region 3 is more than 10 microns.

It may be appreciated that the edge of the moisture discharge hole 110 refers to an edge of the moisture discharge hole 110 close to the channel region 3, and the edge of the channel region 3 refers to an edge of the channel region 3 close to the moisture discharge hole 110. By making the distance between the edge of the moisture discharge hole 110 and the edge of the channel region 3 greater than 10 microns, the path length of hydrogen ions in the second passivation layer 90 invading the channel region 3 is further increased.

In the present embodiment, by making the distance of the moisture discharge hole 110 from the channel region 3 greater than 10 microns, the path length of the hydrogen ions in the second passivation layer 90 invading the channel region 3 is increased, thereby further alleviating the technical problem of the negative offset of voltage of the ESD diode structure 2.

In an embodiment, the hydrogen barrier layer 80 is disposed in the same layer as the common electrode layer.

The common electrode layer includes a common electrode, and the hydrogen barrier layer 80 and the common electrode are spaced apart from each other.

The hydrogen barrier layer 80 and the common electrode layer may be made of the same material.

It may be appreciated that the hydrogen barrier layer 80 and the common electrode layer are formed in the same layer, and are formed of the same material, so that the hydrogen barrier layer 80 and the common electrode layer may be formed using the same photomask, and the hydrogen barrier layer 80 is formed without using an additional photomask.

It should be noted that since the hydrogen barrier layer 80 serves to block hydrogen ions in the second passivation layer 90 from invading the channel region 3 of the active layer 40, the hydrogen barrier layer 80 needs to be provided at a side of the second passivation layer 90 facing the substrate 10, and the hydrogen barrier layer 80 needs to be provided at a side of the active layer 40 away from the substrate 10.

In the present embodiment, the hydrogen barrier layer 80 and the common electrode layer are provided in the same layer, and are formed using the same photomask, and there is no need to use an additional photomask to form the hydrogen barrier layer 80, thereby saving one photomask and reducing costs.

In an embodiment, the material for forming the hydrogen barrier layer 80 includes indium tin oxide.

The material for forming the hydrogen barrier layer 80 may further include a transparent semiconductor material such as indium zinc oxide, indium gallium zinc oxide, and the like.

Referring to FIG. 4, a structure of a array substrate in FIG. 4 is substantially the same as that of the array substrate shown in FIG. 3, except that the moisture discharge hole 110 is further provided to penetrate through the hydrogen barrier layer 80 and the second passivation layer 90, and the array substrate 1 further includes a pixel electrode layer 100 provided at a side of the second passivation layer 90 away from the substrate 10, and the pixel electrode layer 100 is provided to cover the moisture discharge hole 110.

The pixel electrode layer 100 includes a pixel electrode, the pixel electrode is filled in the moisture discharge hole 110 for preventing moisture and oxygen from invading the surface from the moisture discharge hole 110.

It may be appreciated that a moisture discharge hole 110 is disposed to penetrate through the flat layer 70, the hydrogen barrier layer 80, and the second passivation layer 90. Since the moisture discharge hole 110 is disposed to penetrate through the hydrogen barrier layer 80 and the second passivation layer 90, the second passivation layer 90 and the hydrogen barrier layer 80 may be formed by one photomask, and the moisture discharge hole 110 penetrating through the hydrogen barrier layer 80 and the second passivation layer 90 is formed, thereby saving a photomask for forming the hydrogen barrier layer 80.

It should be noted that since the hydrogen barrier layer 80 and the second passivation layer 90 are formed using the same photomask, the hydrogen barrier layer 80 may be a metal layer, an organic layer or a semiconductor layer.

It should be noted that since the second passivation layer 90 and the hydrogen barrier layer 80 are formed by one photomask, and the hydrogen barrier layer 80 is first integrally deposited and is not patterned for the time being, the integrally deposited hydrogen barrier layer 80 may effectively block the implantation of hydrogen ions of the second passivation layer 90 when the second passivation layer 90 is formed, so that the hydrogen ions may be blocked and no hydrogen ions enter the ESD diode structure 2.

It should be noted that when the moisture discharge hole 110 is provided to penetrate through the flat layer 70, the hydrogen barrier layer 80, and the second passivation layer 90, although the hydrogen barrier layer 80 is provided with the moisture discharge hole 110, the hydrogen barrier layer 80 is provided as a whole when the second passivation layer 90 is formed, so that the channel region 3 is not invaded by hydrogen ions in the second passivation layer 90. At the same time, since the water molecules in the flat layer 70 are partially discharged when the flat layer 70 is heated or baked, the water molecules in the flat layer 70 are further discharged when the hydrogen barrier layer 80 is heated or baked, and the pixel electrode layer 100 is filled in the moisture discharge hole 110 so that the water molecules at a side of the second passivation layer 90 away from the substrate 10 may be blocked from invading the channel region 3 along the moisture discharge hole 110. That is, when the moisture discharge hole 110 is provided to penetrate through the flat layer 70 and the hydrogen barrier layer 80, there is no hydrogen ion to invade the channel region 3 and a tiny small amount of water molecules to invade the channel region 3.

Therefore, with respect to the embodiments of FIGS. 2 and 3, the effect of present embodiment, i.e., the embodiment of FIG. 4 is optimal, and it is possible to realize that there is no hydrogen ion invasion at the channel region 3 and there is little water molecule invasion.

In the present embodiment, the second passivation layer 90 and the hydrogen barrier layer 80 are formed using the same photomask, and the moisture discharge hole 110 penetrating through the flat layer 70, the hydrogen barrier layer 80 and the second passivation layer 90 is formed, thereby saving a photomask for forming the hydrogen barrier layer 80 and reducing costs.

In an embodiment, the hydrogen barrier layer 80 is a metal layer or an organic layer made of, a material for forming the metal layer includes at least one of copper, aluminum, or molybdenum titanium alloy, and the organic layer is a polymer material.

In an embodiment, the array substrate 1 further includes a flat layer 70, a common electrode layer and a second passivation layer 90, the hydrogen barrier layer 80 is disposed at a side of the first passivation layer 60 away from the substrate 10, the flat layer 70 is disposed at a side of the hydrogen barrier layer 80 away from the substrate 10, the common electrode layer is disposed at a side of the first passivation layer 60 away from the substrate 10, and the second passivation layer 90 is disposed at a side of the common electrode layer away from the substrate 10.

It may be appreciated that by disposing the hydrogen barrier layer 80 at the side of the first passivation layer 60 away from the substrate 10 and disposing the hydrogen barrier layer 80 at the side of the flat layer 70 facing the substrate 10, the hydrogen barrier layer 80 is not only capable of blocking the invasion of hydrogen ions in the second passivation layer 90 into the channel region 3, but also of blocking the invasion of water molecules in the flat layer 70 into the channel region 3.

In the present embodiment, by disposing the hydrogen barrier layer 80 at the side of the flat layer 70 facing the substrate 10, the water molecules in the flat layer 70 and the hydrogen ions in the second passivation layer 90 are blocked from invading the channel region 3, the negative offset of voltage of the ESD diode structure 2 is improved, and stability of the ESD diode structure 2 is improved.

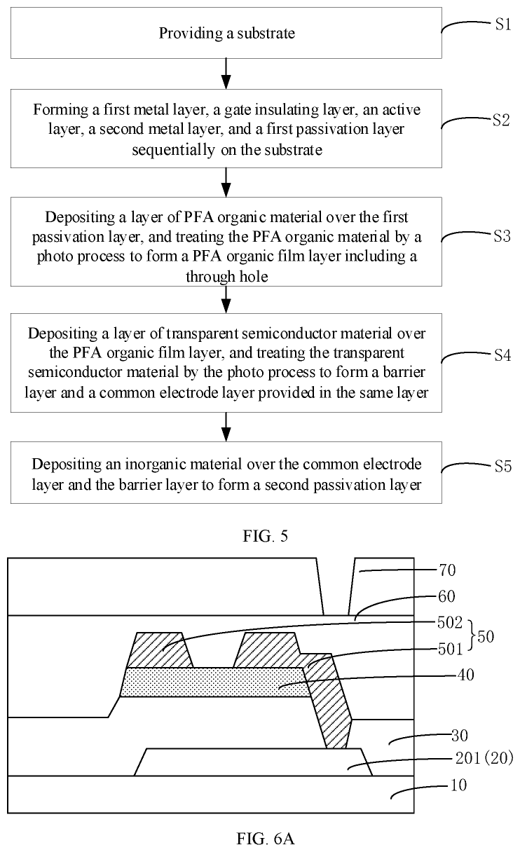

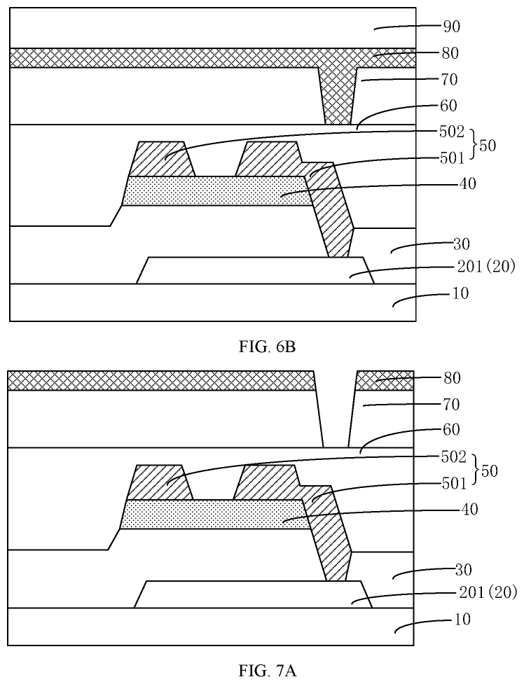

Referring to FIGS. 5 and 6A to 6B, the present disclosure further provides a method of manufacturing the array substrate 1 including following steps.

At step S1, a substrate 10 is provided.

At step S2, a second metal layer 20, a gate insulating layer 30, an active layer 40, a first metal layer 50, and a first passivation layer 60 are sequentially formed on the substrate 10;

At step S3, a layer of PFA organic material is deposited over the first passivation layer 60, and the PFA organic material is treated by a photo (or photolithgraphy) process to form a flat layer 70 having a moisture discharge hole 110;

At step S4, a layer of transparent semiconductor material is deposited over the flat layer 70, and the transparent semiconductor material is treated by a photo process (or yellow light process, photolithographic technology) to form a hydrogen barrier layer 80 and a common electrode layer, which are provided in the same layer;

At step S5, an inorganic material is deposited over the common electrode layer and the hydrogen barrier layer 80 to form a second passivation layer 90.

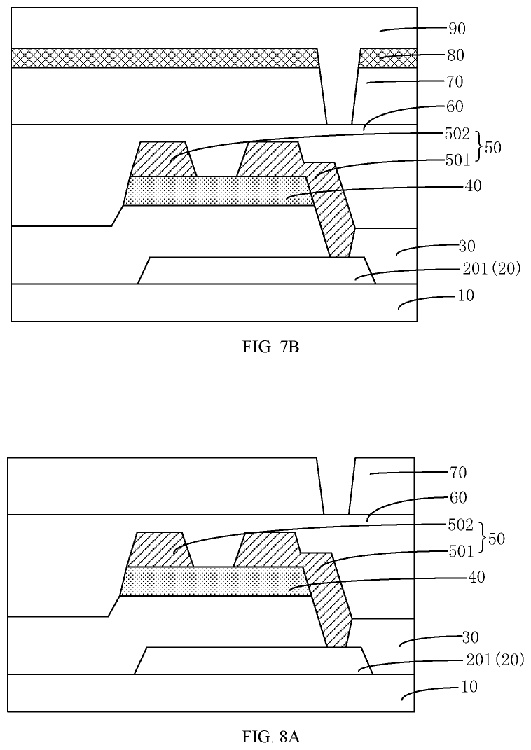

In an embodiment, referring to FIGS. 7A and 7B, the step of treating the transparent semiconductor material by the photo process to form the hydrogen barrier layer 80 and the common electrode layer which are disposed in the same layer further includes: the transparent semiconductor material is treated by the photo process so that a moisture discharge hole 110 is also formed through the hydrogen barrier layer 80.

Referring to FIG. 7A, the moisture discharge hole 110 extends through the flat layer 70 and the hydrogen barrier layer 80. In this case, when heating or baking of the flat layer 70 is performed, water molecules in the flat layer 70 are discharged along the moisture discharge hole 110, and when heating or baking of the hydrogen barrier layer 80 is performed, water molecules in the flat layer 70 are further discharged along the moisture discharge hole 110, thereby increasing the discharge amount of water molecules in the flat layer 70 and reducing the content of water molecules in the flat layer 70, thereby alleviating a technical problem in the prior art that the channel region 3 of the lower active layer 40 is prone to be invaded by the water molecules in the flat layer 70.

Referring to FIG. 7B, the second passivation layer 90 covers the hydrogen barrier layer 80 and the moisture discharge hole 110. The second passivation layer 90 is partially filled in the moisture discharge hole 110. The second passivation layer 90 is an inorganic material and has water resistance. Therefore, the second passivation layer 90 is filled in the moisture discharge hole 110, it is possible to prevent external water molecules from invading the channel region 3 along the moisture discharge hole 110, thereby further reducing the invasion and influence of water molecules on the channel region 3 of the active layer 40.

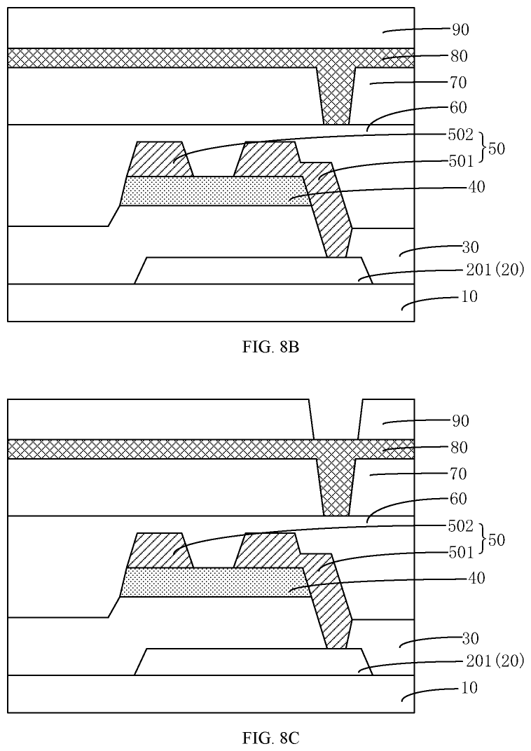

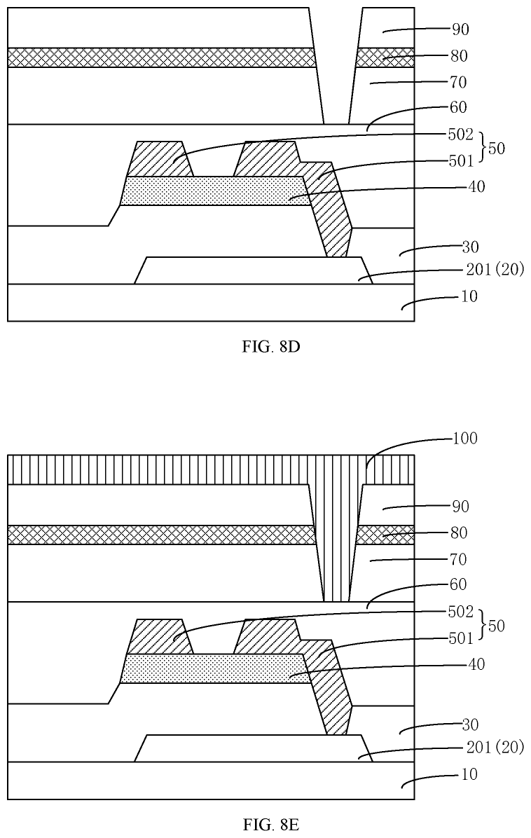

In another embodiment, referring to FIGS. 8A to 8E, the step of forming the hydrogen barrier layer 80 and forming the second passivation layer 90 further includes: a whole layer of material forming the hydrogen barrier layer 80 is deposited, and then a whole layer of an inorganic material is deposited; and the material of the hydrogen barrier layer 80 and the inorganic material is treated by a photo process using one photomask to form the hydrogen barrier layer 80 and the second passivation layer 90, and the moisture discharge hole 110 penetrates through the flat layer 70, the hydrogen barrier layer 80, and the second passivation layer 90.

Referring to FIG. 8A, in forming the flat layer 70, a moisture discharge hole 110 is formed through the flat layer 70, and the moisture discharge hole 110 is used to discharge water molecules in the flat layer 70 and reduce the water molecule content of the flat layer 70.

Referring to FIG. 8B, the hydrogen barrier layer 80 is first deposited on a whole surface, and the second passivation layer 90 is also deposited on a whole surface. In this case, the hydrogen ions during the deposition of the second passivation layer 90 cannot invade the lower channel region 3 due to the blocking of the hydrogen barrier layer 80.

Referring to FIG. 8C, the second passivation layer 90 is treated by a photo process using one photomask.

Referring to FIG. 8D, the hydrogen barrier layer 80 is treated by a photo process using the same photomask to form a moisture discharge hole 110 extending through the flat layer 70, the hydrogen barrier layer 80, and the second passivation layer 90. After the moisture discharge hole 110 is formed, the hydrogen barrier layer 80 is heated or baked, so that water molecules in the flat layer 70 are further discharged along the moisture discharge hole 110. It should be noted that since the hydrogen barrier layer 80 and the second passivation layer 90 are treated by the photo process using the same photomask, it is also possible to save one photomask and reduce costs.

Referring to FIG. 8E, a pixel electrode layer 100 is formed on the second passivation layer 90, and the pixel electrode layer 100 is provided to cover the moisture discharge hole 110. The pixel electrode layer 100 is filled in the moisture discharge hole 110, so that external water molecules may be prevented from invading the channel region 3 along the moisture discharge hole 110, thereby further reducing the invasion and influence of the water molecules on the channel region 3.

It may be appreciated that the hydrogen barrier layer 80 and the second passivation layer 90 are formed using the same photomask, and that the hydrogen barrier layer 80 is provided on a whole surface when the material of the second passivation layer 90 is deposited, so that hydrogen ions of the second passivation layer 90 may not invade the channel region 3.

It should be noted that after the moisture discharge hole 110 is formed through the flat layer 70, the hydrogen barrier layer 80, and the second passivation layer 90, heating or baking of the hydrogen barrier layer 80 is performed. At this time, a part of the water molecules of the flat layer 70 may be discharged through the moisture discharge hole 110.

In the present embodiment, the hydrogen barrier layer 80 is formed using a photomask of the second passivation layer 90, and the moisture discharge hole 110 is provided to penetrate through the flat layer 70, the hydrogen barrier layer 80, and the second passivation layer 90, so that not only can the hydrogen ions in the second passivation layer 90 be completely prevented from invading the channel region 3, but also water molecules in the flat layer 70 can be discharged from the moisture discharge hole 110 by heating or baking of the flat layer 70 and the hydrogen barrier layer 80, thereby further improving the negative offset of voltage of the ESD diode structure 2 and improving the stability of the ESD diode structure 2.

The present disclosure further provides a display panel, a display module, and a display device, the display panel, the display module, and the display device each include the array substrate described above, and details are not described herein.

An array substrate provided in this embodiment includes a substrate, an active layer, a first metal layer, a first passivation layer, a flat layer, and a second passivation layer. The active layer is disposed above the substrate, the first metal layer is disposed at a side of the active layer away from the substrate, the first metal layer includes a source and a drain, the first passivation layer is disposed at a side of the first metal layer away from the substrate, the flat layer is disposed at a side of the first passivation layer away from the substrate, and the second passivation layer is disposed at a side of the flat layer away from the substrate. The active layer includes doped regions in contact with the source and the drain, and a channel region between adjacent doped regions, the array substrate further includes at least one hydrogen barrier layer disposed at a side of the active layer away from the substrate, the hydrogen barrier layer is disposed at a side of the second passivation layer facing the substrate, and the hydrogen barrier layer is disposed to cover at least the channel region. The hydrogen barrier layer is provided above the channel region of the ESD diode structure, and the hydrogen barrier layer is provided to cover at least the channel region, hydrogen ions in the second passivation layer are blocked from diffusing into the channel region of the active layer by the hydrogen barrier layer, and water molecules in the flat layer are discharged through a moisture discharge hole penetrating through at least the flat layer, so that invasion and influence of water molecules and hydrogen ions on the channel region are reduced, thereby alleviating a technical problem that the negative offset of voltage occurs in an ESD diode structure in an existing array substrate.

In the above-mentioned embodiments, the description of each embodiment has its own emphasis. For parts not described in detail in a certain embodiment, reference may be made to the related description of other embodiments.

The array substrate, the display panel, and the method of manufacturing the array substrate provided in the embodiments of the present invention are described in detail. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of application in accordance with the teachings of the present disclosure. In view of the foregoing, the content of the present specification should not be construed as limiting the disclosure.

1. An array substrate comprising:
a substrate;
an active layer disposed above the substrate, the active layer comprising doped regions and one or more channel regions;
a first metal layer disposed at a side of the active layer away from the substrate, the first metal layer comprising a source and a drain, the source and the drain being in contact with the doped regions respectively;
a first passivation layer disposed at a side of the first metal layer away from the substrate;
a flat layer disposed at a side of the first passivation layer away from the substrate, the flat layer being provided with one or more moisture discharge holes;
a second passivation layer disposed at a side of the flat layer away from the substrate; and
one or more hydrogen barrier layers disposed between the active layer and the second passivation layer, the hydrogen barrier layers covering at least the channel regions.

2. The array substrate according to claim 1, wherein each of the moisture discharge holes is disposed to penetrate through at least the flat layer.

3. The array substrate according to claim 2, wherein a depth of each of the moisture discharge holes is equal to a thickness of the flat layer.

4. The array substrate according to claim 3, wherein a corresponding hydrogen barrier layer of the hydrogen barrier layers above any one of the one or more channel regions is arranged continuously.

5. The array substrate according to claim 2, wherein each of the moisture discharge holes is disposed to penetrate through the flat layer and a corresponding hydrogen barrier layer of the hydrogen barrier layers, and at least a portion of the second passivation layer is disposed within the moisture discharge holes.

6. The array substrate according to claim 5, wherein a distance between an edge of each of the moisture discharge holes and an edge of a corresponding channel region of the channel regions is greater than 10 microns.

7. The array substrate according to claim 1, wherein the array substrate further comprises a common electrode layer, the common electrode layer is disposed between the flat layer and the second passivation layer, the hydrogen barrier layers and the common electrode layer are disposed in a same layer.

8. The array substrate according to claim 7, wherein the common electrode layer comprises a common electrode, and the hydrogen barrier layers are spaced apart from the common electrode.

9. The array substrate according to claim 8, wherein the hydrogen barrier layers are formed of a same material as the common electrode layer.

10. The array substrate according to claim 1, wherein each of the moisture discharge holes is disposed to penetrate through the flat layer, and each of the hydrogen barrier layers is filled in a corresponding moisture discharge hole of the moisture discharge holes.

11. The array substrate according to claim 1, wherein each of the moisture discharge holes is disposed to penetrate through the flat layer, a corresponding hydrogen barrier layer of the hydrogen barrier layers, and the second passivation layer, the array substrate further comprises a pixel electrode layer disposed at a side of the second passivation layer away from the substrate, and the pixel electrode layer is filled in the moisture discharge holes.

12. The array substrate according to claim 1, wherein the hydrogen barrier layers are disposed at the side of the first passivation layer away from the substrate, and the flat layer is disposed at a side of each of the hydrogen barrier layers away from the substrate.

13. The array substrate according to claim 1, wherein a depth of each of the moisture discharge holes is less than a thickness of the flat layer.

14. The array substrate according to claim 1, wherein a part of the moisture discharge holes are disposed to penetrate through the flat layer, and a depth of each of another part of the moisture discharge holes is less than a thickness of the flat layer.

15. The array substrate according to claim 1, wherein the moisture discharge holes are arranged at equal intervals.

16. The array substrate according to claim 1, wherein a material for forming the hydrogen barrier layers comprises at least one of indium tin oxide, indium zinc oxide, or indium gallium zinc oxide.

17. The array substrate according to claim 1, wherein the array substrate further comprises a second metal layer, the second metal layer is disposed on the substrate, and the second metal layer comprises a gate, the source is connected to the gate.

18. A display panel comprising the array substrate according to claim 1.

19. A method of manufacturing an array substrate, comprising:
providing a substrate;
forming a second metal layer, a gate insulating layer, an active layer, a first metal layer, and a first passivation layer sequentially on the substrate;
depositing a layer of PFA organic material over the first passivation layer, and treating the PFA organic material by a photo process to form a flat layer including one or more moisture discharge holes;
depositing a layer of transparent semiconductor material over the flat layer, and treating the transparent semiconductor material by the photo process to form one or more hydrogen barrier layers and a common electrode layer provided in a same layer; and
depositing an inorganic material over the common electrode layer and the hydrogen barrier layers to form a second passivation layer.

20. The method according to claim 19, wherein the forming of the hydrogen barrier layers and the forming of the second passivation layer further comprises: depositing an entire layer of a material of the hydrogen barrier layers, then depositing an entire layer of an inorganic material, and performing the photo process on the material of the hydrogen barrier layers and the inorganic material using one photomask to form the hydrogen barrier layers and the second passivation layer, wherein the moisture discharge holes penetrate through the flat layer, the hydrogen barrier layers, and the second passivation layer.
